(19) United States
(12) Patent Application Publication
(10) Pub. No.: US 2025/0228030 A1
(43) Pub. Date: Jul. 10, 2025

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventors: SHINJI NAKAGAWA, KANAGAWA (JP); KENJI FUJIYAMA, KANAGAWA (JP); YOHEI HIROSE, KANAGAWA (JP); TAKUYA TOYOFUKU, KANAGAWA (JP)

(21) Appl. No.: 18/849,343

(22) PCT Filed: Feb. 14, 2023
(86) PCT No.: PCT/JP2023/004947

§ 371 Date: Sep. 20, 2024

(30) Foreign Application Priority Data
Mar. 29, 2022 (JP) 2022-053968

(51) Int. Cl. H10F 39/00

(52) U.S. Cl. CPC H10F 39/811; H10F 39/8037; H10F 39/807; H10F 39/809

(57) ABSTRACT

Provided is a photodetection device that can be connected to ground without using a special process for a pixel including an inter-pixel separation portion of a conductive material. The photodetection device includes a substrate portion including a pixel region in which a plurality of pixels capable of generating charges according to light incident from the outside is arranged in a matrix, and a peripheral region different from the pixel region. Each of the plurality of pixels includes a plurality of inter-pixel separation portions that defines an outer edge of the pixel, is formed to extend from a light incident surface of the substrate portion to a surface opposite to the light incident surface, and insulates and shields the pixels adjacent. At least a part of the plurality of inter-pixel separation portions is formed to extend to the peripheral region. In the peripheral region, a grounding portion connectable to the inter-pixel separation portion and configured to apply a predetermined voltage to the pixel via the inter-pixel separation portion is provided.

### TECHNICAL FIELD

The present disclosure relates to a photodetection device and an electronic apparatus including the photodetection device.

### BACKGROUND ART

Conventionally, in an electronic apparatus having an imaging function such as a digital still camera or a digital video camera, for example, a solid-state imaging element such as a charge coupled device (CCD) or a complementary metal oxide semiconductor (CMOS) image sensor is used as a photodetection device. The photodetection device includes a pixel in which a photodiode (photoelectric conversion element) that performs photoelectric conversion and a transistor are combined, and an image is constructed on the basis of pixel signals output from a plurality of pixels arranged in a plane.

For example, in a solid-state imaging element, charges accumulated in a photodiode are transferred to a floating diffusion (FD) section having a predetermined capacitance provided in a connection portion between the photodiode and a gate electrode of an amplification transistor. Then, a pixel signal corresponding to the amount of electric charge accumulated in the FD section is read from the pixel, subjected to analog-digital (AD) conversion by an AD conversion circuit including a comparator, and output.

Meanwhile, in a case where strong light is incident on a pixel, a phenomenon called color mixing may occur in which charges accumulated in a photodiode of the pixel are saturated and overflow, and leak to an adjacent pixel. Therefore, a solid-state imaging element has been proposed in which an inter-pixel separation portion that separates pixels is configured by a full trench (for example, Patent Document 1).

### CITATION LIST

### Patent Document

Patent Document 1: WO 2017/130723 A

### SUMMARY OF THE INVENTION

### Problems to be Solved by the Invention

However, in the solid-state imaging element described in the above Patent Document 1, since an inter-pixel separation portion is formed between all pixels, it is necessary to perform GND connection for each pixel.

The present disclosure has been made in view of such circumstances, and an object of the present disclosure is to provide a photodetection device and an electronic apparatus that can be connected to ground without using a special process for a pixel including an inter-pixel separation portion of a conductive material.

### Solutions to Problems

An aspect of the present disclosure is a photodetection device including a substrate portion including a pixel region in which a plurality of pixels capable of generating charges according to light incident from outside is arranged in a matrix, and a peripheral region different from the pixel region, in which each of the plurality of pixels includes a plurality of inter-pixel separation portions that defines an outer edge of the pixel, is formed to extend from a light incident surface of the substrate portion to a surface opposite to the light incident surface, and insulates and shields the pixels adjacent, at least a part of the plurality of inter-pixel separation portions is formed to extend to the peripheral region, and a grounding portion connectable to the inter-pixel separation portion and configured to apply a predetermined voltage to the pixel via the inter-pixel separation portion is provided in the peripheral region.

Another aspect of the present disclosure is a photodetection device including: a first substrate portion including a pixel region in which a plurality of pixels capable of generating charges according to light incident from outside is arranged in a matrix, and a peripheral region different from the pixel region; and a second substrate portion laminated on an element surface of the first substrate portion on a side opposite to a light incident surface on which the light is incident, the second substrate portion including a readout circuit that outputs a pixel signal based on a charge output from the pixel, in which each of the plurality of pixels includes a plurality of inter-pixel separation portions that defines an outer edge of the pixel, is formed to extend from the light incident surface of the first substrate portion to the element surface, and insulates and shields the pixels adjacent, the inter-pixel separation portion is formed to extend to the peripheral region, and a grounding portion connectable to the inter-pixel separation portion and configured to apply a predetermined voltage to the pixel via the inter-pixel separation portion is provided in the peripheral region.

Furthermore, another aspect of the present disclosure is an electronic apparatus including a photodetection device including a substrate portion including a pixel region in which a plurality of pixels capable of generating charges according to light incident from outside is arranged in a matrix, and a peripheral region different from the pixel region, in which each of the plurality of pixels includes a plurality of inter-pixel separation portions that defines an outer edge of the pixel, is formed to extend from a light incident surface of the substrate portion to a surface opposite to the light incident surface, and insulates and shields the pixels adjacent, at least a part of the plurality of inter-pixel separation portions is formed to extend to the peripheral region, and a grounding portion connectable to the inter-pixel separation portion and configured to apply a predetermined voltage to the pixel via the inter-pixel separation portion is provided in the peripheral region.

Furthermore, another aspect of the present disclosure is an electronic apparatus including a photodetection device including: a first substrate portion including a pixel region in which a plurality of pixels capable of generating charges according to light incident from outside is arranged in a matrix, and a peripheral region different from the pixel region; and a second substrate portion laminated on an element surface of the first substrate portion on a side opposite to a light incident surface on which the light is incident, the second substrate portion including a readout circuit that outputs a pixel signal based on a charge output from the pixel, in which each of the plurality of pixels includes a plurality of inter-pixel separation portions that defines an outer edge of the pixel, is formed to extend from the light incident surface of the first substrate portion to the element surface, and insulates and shields the pixels adjacent, the inter-pixel separation portion is formed to extend to the peripheral region, and a grounding portion connectable to the inter-pixel separation portion and configured to apply a predetermined voltage to the pixel via the inter-pixel separation portion is provided in the peripheral region.

### BRIEF DESCRIPTION OF DRAWINGS

FIG. 1 is a schematic diagram illustrating a configuration example of a photodetection device according to a first embodiment of the present disclosure.

FIG. 2 is a circuit diagram illustrating a configuration example of a pixel unit PU of the photodetection device.

FIG. 3 is a cross-sectional view of a first substrate and a second substrate on which the pixel unit illustrated in FIG. 2 is formed.

FIG. 4 is a plan view for explaining a comparative example of the first embodiment.

FIG. 5 is a cross-sectional view for explaining a connection state between a p-well and a GND wiring in a comparative example of the first embodiment.

FIG. 6 is a plan view for explaining a state in which an inter-pixel separation portion extends to a peripheral region and is grounded to a GND wiring in the first embodiment of the present disclosure.

FIG. 7 is a partial longitudinal cross-sectional view of the semiconductor structure taken along line A-A′ in FIG. 6.

FIG. 8 is a partial longitudinal cross-sectional view illustrating an example of a semiconductor structure in a peripheral region according to a modification of the first embodiment of the present disclosure.

FIG. 9 is a partial longitudinal cross-sectional view illustrating an example of a semiconductor structure in a peripheral region of a photodetection device according to a second embodiment of the present disclosure.

FIG. 10 is a partial longitudinal cross-sectional view illustrating an example of a semiconductor structure in a peripheral region of a photodetection device according to a first modification of the second embodiment of the present disclosure.

FIG. 11 is a partial longitudinal cross-sectional view illustrating an example of a semiconductor structure in a peripheral region of a photodetection device according to a second modification of the second embodiment of the present disclosure.

FIG. 12 is a partial longitudinal cross-sectional view illustrating an example of a semiconductor structure in a peripheral region of a photodetection device according to a third modification of the second embodiment of the present disclosure.

FIG. 13A is a plan view of a pixel region and a peripheral region of a photodetection device according to a third embodiment of the present disclosure as viewed from a front surface side of a first substrate.

FIG. 13B is an enlarged view of a portion indicated by an alternate long and short dash line in the peripheral region of FIG. 13A.

FIG. 14 is a partial longitudinal cross-sectional view illustrating an example of a semiconductor structure in a peripheral region of a photodetection device according to the third embodiment of the present disclosure.

FIG. 15 is a plan view of a part of a pixel region and a peripheral region of a photodetection device according to a modification of the third embodiment of the present disclosure as viewed from a front surface side of a first substrate.

FIG. 16 is a plan view of a part of a pixel region and a peripheral region of a photodetection device according to a fourth embodiment of the present disclosure as viewed from a front surface side of a first substrate.

FIG. 17 is a partial longitudinal cross-sectional view of the semiconductor structure taken along line A-A′ in FIG. 16.

FIG. 18 is a partial longitudinal cross-sectional view illustrating an example of a semiconductor structure in a peripheral region of a photodetection device according to a modification of the fourth embodiment of the present disclosure.

FIG. 19 is a plan view of a part of a pixel region and a peripheral region of a photodetection device according to a fifth embodiment of the present disclosure as viewed from a front surface side of a first substrate.

FIG. 20 is a plan view of a part of a pixel region and a peripheral region of a photodetection device according to a sixth embodiment of the present disclosure as viewed from a front surface side of a first substrate.

FIG. 21 is a plan view of a part of a pixel region and a peripheral region of a photodetection device according to a seventh embodiment of the present disclosure as viewed from a front surface side of a first substrate.

FIG. 22 is a plan view of a part of a pixel region and a peripheral region of a photodetection device according to an eighth embodiment of the present disclosure as viewed from a front surface side of a first substrate.

FIG. 23 is a block diagram illustrating a configuration example of an electronic apparatus to which the present technology is applied.

FIG. 24 is a view depicting an example of a schematic configuration of an endoscopic surgery system.

FIG. 25 is a block diagram depicting an example of a functional configuration of a camera head and a camera control unit (CCU).

FIG. 26 is a block diagram depicting an example of schematic configuration of a vehicle control system.

FIG. 27 is a diagram of assistance in explaining an example of installation positions of an outside-vehicle information detecting section and an imaging section.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs to avoid the description from being redundant. However, it should be noted that the drawings are schematic, and the relationship between thickness and planar dimension, the ratio of thickness of each device or each member, and the like differ from actual ones. Therefore, specific thicknesses and dimensions should be determined in consideration of the following description. Further, it goes without saying that dimensional relationships and ratios are partly different between the drawings.

In the present specification, a “first conductivity type” means one of the p-type and the n-type, and a “second conductivity type” means one of the p-type and the n-type different from the “first conductivity type”. Furthermore, “n” or “p” to which “+” or “−” is added means a semiconductor region having a relatively higher or lower impurity density than that of a semiconductor region to which “+” or “−” is not added. However, even in the semiconductor regions to which the same “n” and “n” are added, it does not mean that the impurity densities of the semiconductor regions are exactly the same.

Further, definitions of directions such as upward and downward directions in the following description are merely definitions for convenience of description and do not limit the technical idea of the present disclosure. For example, it goes without saying that if a target is observed while being rotated by 90°, the upward and downward directions are converted into rightward and leftward, and if the target is observed while being rotated by 180°, the upward and downward are inverted.

Note that the effects described in the present specification are merely examples and are not limited, and other effects may be provided.

### First Embodiment

### (Overall Configuration of Photodetection Device)

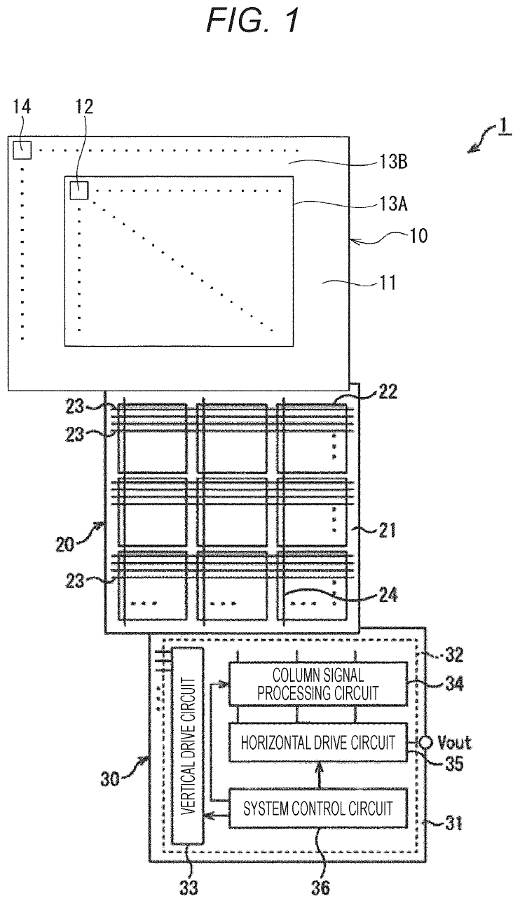

FIG. 1 is a schematic diagram depicting a configuration example of a photodetection device according to a first embodiment of the present disclosure. The photodetection device 1 captures image light from a subject via an optical lens (not illustrated), converts a light amount of incident light formed on an imaging surface into an electrical signal in units of pixels, and outputs the electrical signal as a pixel signal.

As depicted in FIG. 1, a photodetection device 1 is configured by bonding three substrates, i.e., a first substrate 10, a second substrate 20, and a third substrate 30. The first substrate 10, the second substrate 20, and the third substrate 30 are laminated in this order.

The first substrate 10 includes, on the first semiconductor substrate 11, a rectangular pixel region 13A provided in a central portion, and a peripheral region 13B arranged outside the pixel region 13A so as to surround the pixel region 13A. The pixel region 13A is, for example, a light receiving surface that receives light condensed by the optical lens. Then, in the pixel region 13A, a plurality of sensor pixels 12 is arranged in a matrix. In other words, the sensor pixels 12 are repeatedly arranged in the respective directions of the row direction and the column direction orthogonal to each other in the two-dimensional plane.

As illustrated in FIG. 1, a plurality of bonding pads 14 is disposed in the peripheral region 13B. Each of the plurality of bonding pads 14 is arranged, for example, along four sides in a two-dimensional plane of the first semiconductor substrate 11. Each of the plurality of bonding pads 14 is an input/output terminal used when the first semiconductor substrate 11 is electrically connected to an external device.

The second substrate 20 includes, on a second semiconductor substrate 21, readout circuits 22 that read out pixel signals based on charges output from the sensor pixels 12, each of which is provided per four sensor pixels 12. The second substrate 20 includes a plurality of pixel drive lines 23 extending in a row direction and a plurality of vertical signal lines 24 extending in a column direction.

The third substrate 30 includes a logic circuit 32 that processes a pixel signal on a third semiconductor substrate 31. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout for each sensor pixel 12 to the outside. In the logic circuit 32, a low-resistance region, which is constituted by a silicide formed by using a self aligned silicide (salicide) process such as CoSi2 or NiSi, may be formed on, for example, a surface of an impurity diffusion region that is in contact with a source electrode and a drain electrode.

The vertical drive circuit 33 sequentially selects the plurality of sensor pixels 12 row by row, for example. The column signal processing circuit 34 performs, for example, correlated double sampling (CDS) processing on the pixel signal output from each sensor pixel 12 in the row selected by the vertical drive circuit 33. For example, the column signal processing circuit 34 extracts a signal level of the pixel signal by performing the CDS processing and holds pixel data corresponding to an amount of light received by each sensor pixel 12. The horizontal drive circuit 35 sequentially outputs the pixel data held in the column signal processing circuit 34 to the outside, for example. The system control circuit 36 controls driving of each block (vertical drive circuit 33, column signal processing circuit 34, and horizontal drive circuit 35) in the logic circuit 32, for example.

### (Circuit Configuration Example of Pixel Unit)

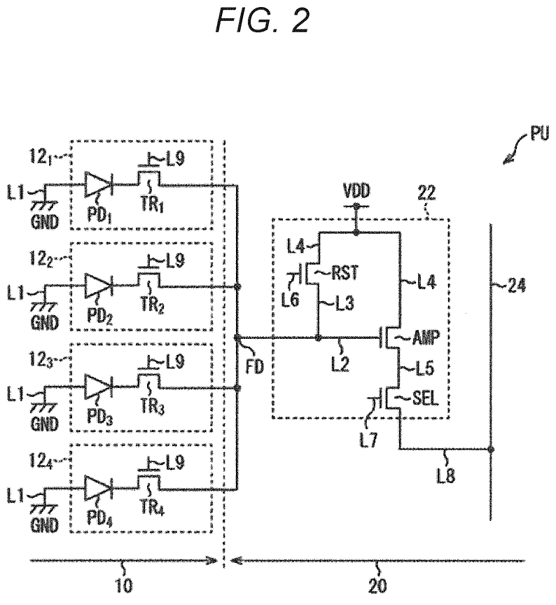

FIG. 2 is a circuit diagram depicting a configuration example of a pixel unit PU of the photodetection device 1.

As depicted in FIG. 2, one pixel unit PU includes four sensor pixels 12 and one readout circuit 22. In other words, one readout circuit 22 is shared by four sensor pixels 12, and outputs of the four sensor pixels 12 are input to the shared readout circuit 22.

Each sensor pixel 12 includes a photodiode PD as a photoelectric conversion element and a transfer transistor TR electrically connected to the photodiode PD.

The readout circuit 22 includes a floating diffusion FD, an amplification transistor AMP, a reset transistor RST, and a selection transistor SEL. Note that the selection transistor SEL may be omitted as necessary.

Hereinafter, in a case where the four sensor pixels 12 connected to one readout circuit 22 are distinguished, the pixels are described as sensor pixels 121 to 124 as depicted in FIG. 2. The photodiodes PD and the transfer transistors TR included in the sensor pixels 121 to 124 are similarly described as photodiodes PD1 to PD4 and transfer transistors TR1 to TR4. Meanwhile, in a case where it is unnecessary to distinguish the four sensor pixels 12, the photodiodes PD, and the transfer transistors TR, subscripts thereof are omitted.

The photodiode PD generates a charge corresponding to an amount of received light by photoelectric conversion. The cathode of the photodiode PD is electrically connected to the source of the transfer transistor TR, and the anode of the photodiode PD is electrically connected to a reference potential line (for example, ground). The drain of the transfer transistor TR is electrically connected to the floating diffusion FD, and the gate electrode of the transfer transistor TR is electrically connected to the pixel drive line 23.

An input terminal of the readout circuit 22 is the floating diffusion FD, and the source of the reset transistor RST is electrically connected to the floating diffusion FD. A predetermined power supply voltage VDD is supplied to the drain of the reset transistor RST together with the drain of the amplification transistor AMP. The gate electrode of the reset transistor RST is electrically connected to the pixel drive line 23 (FIG. 1). The source of the amplification transistor AMP is electrically connected to the drain of the selection transistor SEL, and the gate electrode of the amplification transistor AMP is electrically connected to the source of the reset transistor RST. The source of the selection transistor SEL is an output terminal of the readout circuit 22 and is electrically connected to the vertical signal line 24. The gate electrode of the selection transistor SEL is electrically connected to the pixel drive line 23 (FIG. 1).

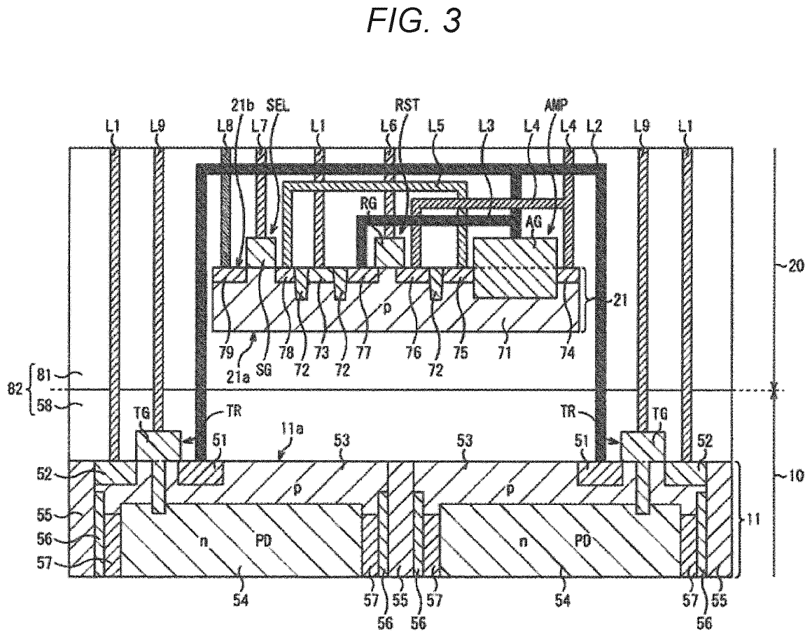

Wires L1 to L9 of FIG. 2 correspond to wires L1 to L9 of FIG. 3 described later.

When the transfer transistor TR is turned on in response to a control signal supplied to the gate electrode via the pixel drive line 23 and the wire L9, the transfer transistor TR transfers a charge of the photodiode PD to the floating diffusion FD. The floating diffusion FD temporarily holds the charge output from the photodiode PD via the transfer transistor TR. The reset transistor RST resets a potential of the floating diffusion FD to a predetermined potential. When the reset transistor RST is turned on, the potential of the floating diffusion FD is reset to the power supply voltage VDD.

The amplification transistor AMP generates a signal of a voltage corresponding to the charge held in the floating diffusion FD as a pixel signal. The amplification transistor AMP forms a source follower circuit with a load MOS (not depicted) serving as a constant current source and outputs a pixel signal having a voltage corresponding to the level of the charge generated in the photodiode PD. When the selection transistor SEL is turned on, the amplification transistor AMP amplifies the potential of the floating diffusion FD and outputs a pixel signal having a voltage corresponding to the potential to the column signal processing circuit 34 via the vertical signal line 24. The selection transistor SEL controls an output timing of the pixel signal from the readout circuit 22. That is, when the selection transistor SEL is turned on, the pixel signal having the voltage corresponding to the level of the charge held in the floating diffusion FD can be output.

The transfer transistor TR, the reset transistor RST, the amplification transistor AMP, and the selection transistor SEL include, for example, an N-type metal oxide semiconductor field effect transistor (MOSFET).

### (Layered Configuration Example of Pixel Unit)

FIG. 3 is a cross-sectional view of the first substrate 10 and the second substrate 20 on which the pixel unit PU is formed.

Note that the cross-sectional view of FIG. 3 is merely a schematic diagram and does not intend to strictly illustrate the actual structure. The cross-sectional view in FIG. 3 includes a portion in which horizontal positions of a transistor and an impurity diffusion layer are intentionally changed to easily explain the configuration of the pixel unit PU included in the photodetection device 1 on the paper.

For example, in FIG. 3, a high-concentration n-type layer (n-type diffusion layer) 51 that is a part of the floating diffusion FD, a gate electrode TG of the transfer transistor TR, and a high-concentration p-type layer (p-type diffusion layer) 52 are arranged side by side in a lateral direction, but, in an actual structure, the high-concentration n-type layer 51, the gate electrode TG, and the high-concentration p-type layer 52 are arranged in a direction perpendicular to the paper surface in some cases. In this case, one of the high-concentration n-type layer 51 and the high-concentration p-type layer 52 is arranged on the front side of the paper with the gate electrode TG interposed therebetween, and the other of the high-concentration n-type layer 51 and the high-concentration p-type layer 52 is arranged on the back side of the paper.

As depicted in FIG. 3, in the photodetection device 1, the first substrate 10 and the second substrate 20 are laminated to form a laminate. The first substrate 10 includes the first semiconductor substrate 11, and the second substrate 20 is laminated on a front surface 11a side of the first semiconductor substrate 11. That is, the second substrate 20 is face-to-back bonded to the first substrate 10.

The transfer transistor TR is provided for each sensor pixel 12 on the front surface 11a side of the first semiconductor substrate 11. The source of the transfer transistor TR is the high-concentration n-type layer 51, and the high-concentration n-type layer 51 provided for each sensor pixel 12 is electrically connected by the wire L2 to form the floating diffusion FD.

A back surface side of the first substrate 10 opposite to the front surface 11a side is a light incident surface. Therefore, the photodetection device 1 is a back-illuminated solid-state imaging device, and a color filter (not illustrated) and an on-chip lens (not illustrated) are provided on the back surface side that is the light incident surface. For example, the color filter and the on-chip lens each are provided for each sensor pixel 12.

The first semiconductor substrate 11 of the first substrate 10 includes, for example, a silicon substrate. A p-type layer 53 (hereinafter, referred to as a p-well 53) that is a well layer is provided in a part of and near the front surface 11a of the first semiconductor substrate 11, and an n-type layer 54 forming the photodiode PD is provided in a region deeper than the p-well 53. The gate electrode TG of the transfer transistor TR extends from the front surface 11a of the first semiconductor substrate 11 to a depth at which the gate electrode penetrates the p-well 53 and reaches the n-type layer 54 serving as the photodiode PD. A reference potential (for example, ground potential: 0 V) is supplied to the high-concentration p-type layer 52 serving as a contact portion of the p-well 53 via the wire L1, and a potential of the p-well 53 is set to the reference potential.

The first semiconductor substrate 11 is provided with an inter-pixel separation portion 55 that electrically separates adjacent sensor pixels 12 from each other. The inter-pixel separation portion 55 has, for example, a conductive material, and is provided to penetrate the semiconductor substrate, that is, extends in the depth direction from the front surface 11a to the back surface 11b of the first semiconductor substrate 11. The inter-pixel separation portion 55 is constituted by, for example, silicon oxide. That is, the sensor pixel 12 includes a semiconductor region defined in a substantially rectangular shape by the inter-pixel separation portion 55. Furthermore, in the first semiconductor substrate 11, a p-type layer 56 and an n-type layer 57 are provided between the inter-pixel separation portion 55 and the photodiode PD (n-type layer 54). The p-type layer 56 is formed on the inter-pixel separation portion 55 side, and the n-type layer 57 is formed on the photodiode PD side.

An interlayer insulating film 58 is provided on the front surface 11a side of the first semiconductor substrate 11. The layer insulating film 58 is, for example, one of a silicon oxide film (SiO), a silicon nitride film (SiN), a silicon oxynitride film (SiON), or a silicon carbonitride film (SiCN), or a film obtained by laminating two or more of these films.

The second semiconductor substrate 21 of the second substrate 20 includes, for example, a silicon substrate. The second semiconductor substrate 21 has a front surface 21a facing the first substrate 10 and a back surface 21b located opposite to the front surface 21a. In FIG. 3, the front surface 21a is a lower surface, and the back surface 21b is an upper surface.

The second semiconductor substrate 21 includes, for example, a p-type layer 71 (hereinafter, referred to as a p-well 71) that is a well layer, and the amplification transistor AMP, the selection transistor SEL, and the reset transistor RST are formed on the back surface 21b side of the second semiconductor substrate 21.

An element isolation layer 72 is formed between the amplification transistor AMP and the reset transistor RST. A high-concentration p-type layer 73 that is a contact portion of the p-well 71 is formed between the selection transistor SEL and the reset transistor RST, and the element isolation layer 72 is also formed between the selection transistor SEL and the high-concentration p-type layer 73 and between the reset transistor RST and the high-concentration p-type layer 73. The element isolation layer 72 has, for example, a shallow trench isolation (STI) structure. The reference potential (for example, ground potential: 0 V) is supplied to the high-concentration p-type layer 73 via the wire L1, and a potential of the p-well 71 is set to the reference potential.

The amplification transistor AMP includes a gate electrode AG, a high-concentration n-type layer 74 as the drain, and a high-concentration n-type layer 75 (hereinafter, referred to as a source portion 75) as the source. The gate electrode AG of the amplification transistor AMP has a structure in which a part thereof is embedded in the depth direction from a substrate surface (back surface 21b) of the second semiconductor substrate 21.

The reset transistor RST includes a gate electrode RG, a high-concentration n-type layer 76 (hereinafter, referred to as a drain portion 76) as the drain, and a high-concentration n-type layer 77 (hereinafter, referred to as a source portion 77) as the source. The selection transistor SEL includes a gate electrode SG, a high-concentration n-type layer 78 as the drain, and a high-concentration n-type layer 79 as the source.

The gate electrode AG of the amplification transistor AMP is connected to the high-concentration n-type layer 51 provided for each sensor pixel 12 in the first semiconductor substrate 11 by the wire L2. Further, the gate electrode AG of the amplification transistor AMP is also connected to the source portion 77 of the reset transistor RST by the wire L3. The high-concentration n-type layer 51 of each sensor pixel 12 including the wires L2 and L3 and the source portion 77 of the reset transistor RST form the floating diffusion FD.

The high-concentration n-type layer 74 serving as the drain of the amplification transistor AMP and the drain portion 76 of the reset transistor RST are connected by the wire L4. A predetermined power supply voltage VDD is supplied to the high-concentration n-type layer 74 and the drain portion 76 via the wire L4.

The source portion 75 of the amplification transistor AMP and the high-concentration n-type layer 78 serving as the drain of the selection transistor SEL are connected by the wire L5.

The gate electrode RG of the reset transistor RST is connected to the pixel drive line 23 via the wire L6, and a drive signal for controlling the reset transistor RST is supplied from the vertical drive circuit 33.

The gate electrode SG of the selection transistor SEL is connected to the pixel drive line 23 via the wire L7, and a drive signal for controlling the selection transistor SEL is supplied from the vertical drive circuit 33. The high-concentration n-type layer 79 serving as the source of the selection transistor SEL is connected to the vertical signal line 24 (FIG. 2) via the wire L8, and a pixel signal having a voltage corresponding to a charge held in the floating diffusion FD is output to the vertical signal line 24 via the wire L8.

The gate electrode TG of the transfer transistor TR is connected to the pixel drive line 23 via the wire L9, and a drive signal for controlling the transfer transistor TR is supplied from the vertical drive circuit 33.

The second substrate 20 includes an insulating film 81 that covers the front surface 21a, a part of the back surface 21b, and side surfaces of the second semiconductor substrate 21. The insulating film 81 is, for example, one of SiO, SiN, SiON, and SiCN, or a film in which two or more thereof are laminated. The inter-eyebrow insulating film 58 of the first substrate 10 and the insulating film 81 of the second substrate 20 are bonded to each other to form the interlayer insulating film 82.

Any metal material can be selected as a material of the wires L1 to L9, and, for example, a portion extending in a laminating direction of the first substrate 10 and the second substrate 20 can be constituted by tungsten (W), and a portion extending in a direction orthogonal to the laminating direction (for example, horizontal direction) can be constituted by copper (Cu) or a Cu alloy containing Cu as a main component.

### Comparative Example of First Embodiment

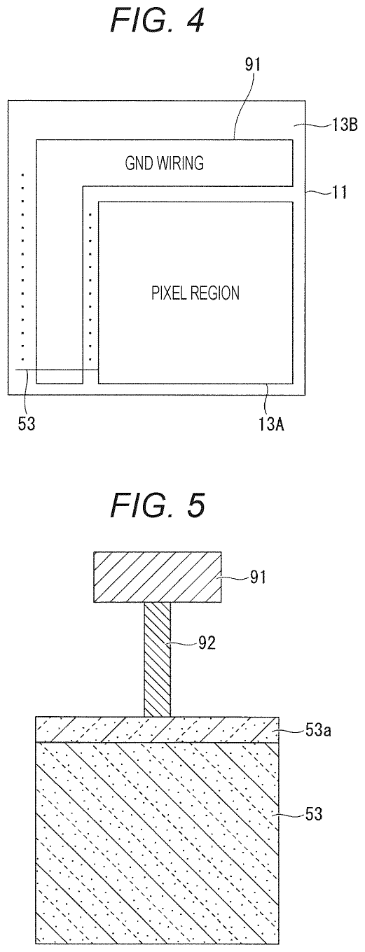

Meanwhile, as illustrated in FIG. 4, the p-well 53 of the pixel region 13A is grounded to a ground (GND) wiring 91 in the peripheral region 13B in order to divide the pixel region 13A and the peripheral region 13B. As illustrated in FIG. 5, the GND wiring 91 is electrically connected to the p-well 53 via a contact 92. In addition, a high-concentration p-type layer 53a is laminated between the p-well 53 and the contact 92. In the peripheral region 13B, the p-well 53 is formed by ion implantation (I.I).

However, in a case where the inter-pixel separation portion 55 surrounding each sensor pixel 12 in the pixel region 13A has a full trench structure penetrating the semiconductor substrate, since each sensor pixel 12 is divided into individual pieces, each sensor pixel 12 needs to be grounded to the GND wiring 91.

### Solving Means of First Embodiment

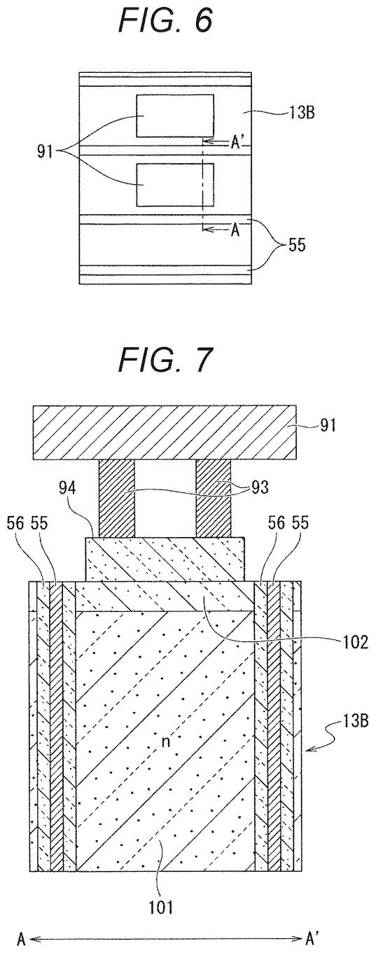

To solve the above problem, in the first embodiment of the present disclosure, as illustrated in FIG. 6, instead of the p-well 53, the inter-pixel separation portion 55 of the pixel region 13A extends to the peripheral region 13B and is grounded to the GND wiring 91. FIG. 7 schematically illustrates a cross section taken along line A-A′ of FIG. 6.

The inter-pixel separation portion 55 and the p-type layer 56 provided on the side wall of the inter-pixel separation portion 55 are extended to the n-type layer 101 of the peripheral region 13B. The GND wiring 91 is electrically connected to the inter-pixel separation portion 55 and the p-type layer 56 via the contact 93, the poly 94, and the high-concentration p-type layer 102. The high-concentration p-type layer 102 is laminated on the n-type layer 101.

### Functions and Effects of First Embodiment

As described above, according to the first embodiment, by extending the plurality of inter-pixel separation portions 55 in the pixel region 13A to the peripheral region 13B and grounding the plurality of inter-pixel separation portions to the GND wiring 91, it is possible to ground the GND around the pixel region 13A without an additional process such as applying the P-type ion implantation in multiple stages.

### Modification of First Embodiment

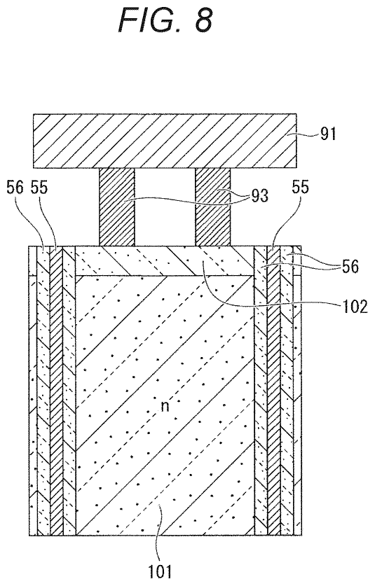

FIG. 8 is a partial longitudinal cross-sectional view illustrating an example of a semiconductor structure of a peripheral region 13B according to a modification of the first embodiment of the present disclosure. In FIG. 8, the same portions as those in the above-described FIG. 7 are denoted by the same reference signs, and detailed description thereof is omitted.

In the first embodiment described above, since the share contact using the poly 94 is used in the pixel region 13A, the GND ground of the peripheral region 13B is also used. However, if the poly 94 is not used in the pixel region 13A, the peripheral region 13B may also directly connect the contact 93 to the high-concentration p-type layer 102.

### Functions and Effects of Modification of First Embodiment

As described above, even in the modification of the first embodiment, functions and effects similar to those of the first embodiment can be obtained.

### Second Embodiment

In the second embodiment of the present disclosure, the GND of the first substrate portion and the GND of the second substrate portion are common via the through contact in the peripheral region, and capacitance enhancement of the GND wiring is realized.

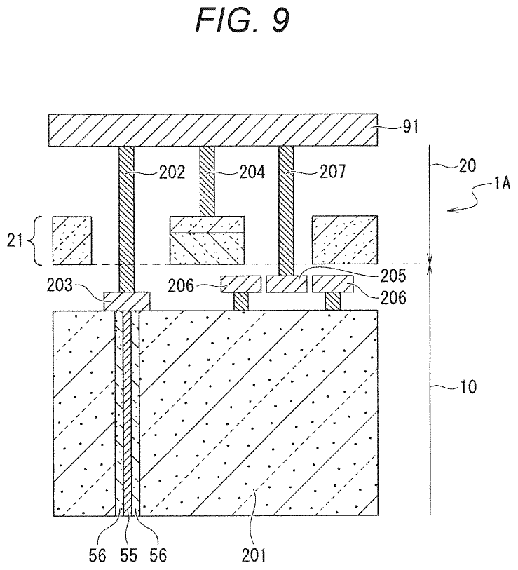

FIG. 9 is a partial longitudinal cross-sectional view illustrating an example of a semiconductor structure in a peripheral region 13B of a photodetection device 1A according to the second embodiment of the present disclosure. In FIG. 9, the same portions as those in the above-described FIG. 7 are denoted by the same reference signs, and detailed description thereof is omitted.

The inter-pixel separation portion 55 and the p-type layer 56 provided on the side wall of the inter-pixel separation portion 55 are extended to the n-type layer 201 of the peripheral region 13B. The GND wiring 91 is electrically connected to the inter-pixel separation portion 55 and the p-type layer 56 via the through contact 202 and the shared poly 203. The through contact 202 penetrates the second substrate 20 provided with the readout circuit 22 and is connected to the shared poly 203 of the substrate 10 provided with the photodiode PD.

Furthermore, the GND wiring 91 is electrically connected to the second semiconductor substrate 21 provided on the second substrate 20 via the through contact 204. Consequently, the GND wiring 91 can be shared by the first substrate 10 and the second substrate 20.

Meanwhile, in the second embodiment of the present disclosure, the first poly wiring 205 and the second poly wiring 206 are laid on the first substrate 10. The first poly wiring 205 is connected to the GND wiring 91 via a through contact 207 penetrating the second substrate 20. The second poly wiring 206 is formed on the first substrate 10 so as to surround the first poly wiring 205. Thus, a capacitance can be imparted between the GND wiring 91 and the second poly wiring 206.

### Functions and Effects of Second Embodiment

As described above, according to the second embodiment, by laying the first poly wiring 205 and the second poly wiring 206 on the first substrate 10 in the peripheral region 13B, it is expected that a capacitance can be imparted between the GND wiring 91 and the second poly wiring 206, thereby suppressing fluctuation of the power supply voltage due to an external factor.

### First Modification of Second Embodiment

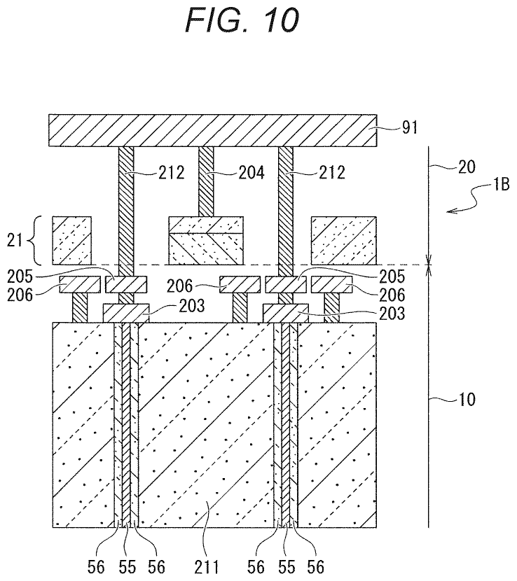

FIG. 10 is a partial longitudinal cross-sectional view illustrating an example of a semiconductor structure in a peripheral region 13B of a photodetection device 1B according to a first modification of the second embodiment of the present disclosure. In FIG. 10, the same portions as those in the above-described FIG. 9 are denoted by the same reference signs, and detailed description thereof is omitted.

The inter-pixel separation portion 55 and the p-type layer 56 provided on the side wall of the inter-pixel separation portion 55 are extended to the n-type layer 211 of the peripheral region 13B. The GND wiring 91 is electrically connected to the inter-pixel separation portion 55 and the p-type layer 56 via the through contact 212, the first poly wiring 205, and the shared poly 203. The through contact 212 penetrates the second substrate 20 and further penetrates the first poly wiring 205 of the substrate 10 to be connected to the shared poly 203. The second poly wiring 206 is formed on the first substrate 10 so as to surround the first poly wiring 205.

### Functions and Effects of First Modification of Second Embodiment

As described above, according to the first modification of the second embodiment, by disposing the first poly wiring 205 on the shared poly 203 so as to pass through the through contact 212, it is possible to impart a capacitance between the GND wiring 91 and the second poly wiring 206 without securing an arrangement space of the first poly wiring 205.

### Second Modification of Second Embodiment

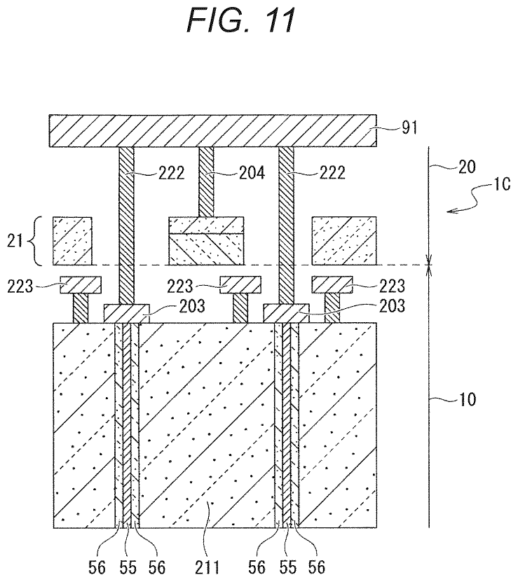

FIG. 11 is a partial longitudinal cross-sectional view illustrating an example of a semiconductor structure in a peripheral region 13B of a photodetection device 1C according to a second modification of the second embodiment of the present disclosure. In FIG. 11, the same portions as those in the above-described FIG. 9 are denoted by the same reference signs, and detailed description thereof is omitted.

The inter-pixel separation portion 55 and the p-type layer 56 provided on the side wall of the inter-pixel separation portion 55 are extended to the n-type layer 221 of the peripheral region 13B. The GND wiring 91 is electrically connected to the inter-pixel separation portion 55 and the p-type layer 56 via the through contact 222 and the shared poly 203.

Meanwhile, in the second modification of the second embodiment of the present disclosure, the poly wiring 223 is laid on the first substrate 10. The poly wiring 223 is formed on the first substrate 10 so as to surround the through contact 222.

### Functions and Effects of Second Modification of Second Embodiment

As described above, according to the second modification of the second embodiment, by laying the poly wiring 223 so as to surround the through contact 222 connecting the shared poly 203, a capacitance can be imparted between the GND wiring 91 and the poly wiring 223.

### Third Modification of Second Embodiment

FIG. 12 is a partial longitudinal cross-sectional view illustrating an example of a semiconductor structure in a peripheral region 13B of a photodetection device 1D according to a third modification of the second embodiment of the present disclosure. In FIG. 12, the same portions as those in the above-described FIG. 9 are denoted by the same reference signs, and detailed description thereof is omitted.

The inter-pixel separation portion 55 and the p-type layer 56 provided on the side wall of the inter-pixel separation portion 55 are extended to the n-type layer 221 of the peripheral region 13B. The GND wiring 91 is electrically connected to the inter-pixel separation portion 55 and the p-type layer 56 via the through contact 202 and the shared poly 203.

Meanwhile, in the third modification of the second embodiment of the present disclosure, the GND wiring 91 is connected to the gate oxide film 231 of the field effect transistor formed on the second semiconductor substrate 21 via the through contact 232. Accordingly, a gate oxide film capacitance is imparted.

### Functions and Effects of Third Modification of Second Embodiment

As described above, according to the third modification of the second embodiment, the gate oxide film capacitance can be imparted using the gate oxide film 231 of the field effect transistor provided on the second substrate 20, whereby it is expected that fluctuation of the power supply voltage due to an external factor can be suppressed.

### Third Embodiment

The third embodiment of the present disclosure realizes the same pixel structure in the pixel region 13A and the peripheral region 13B.

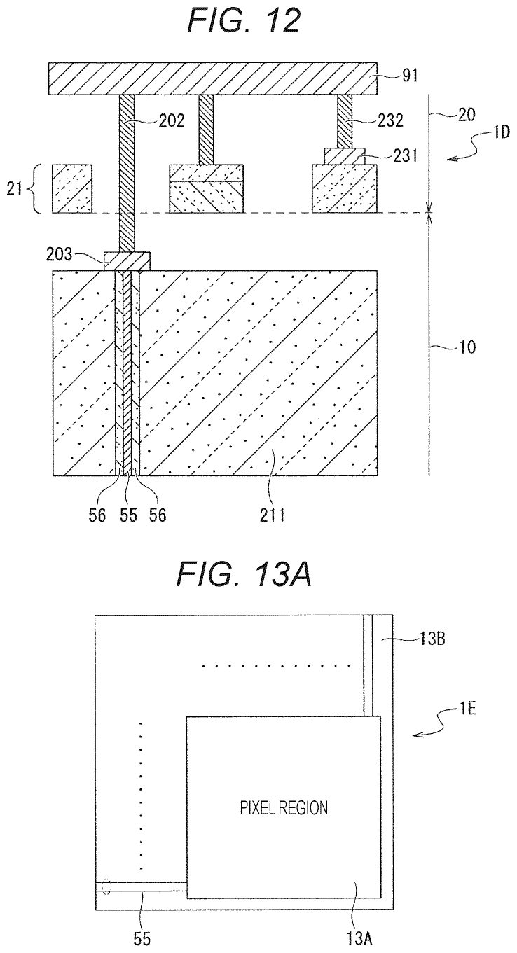

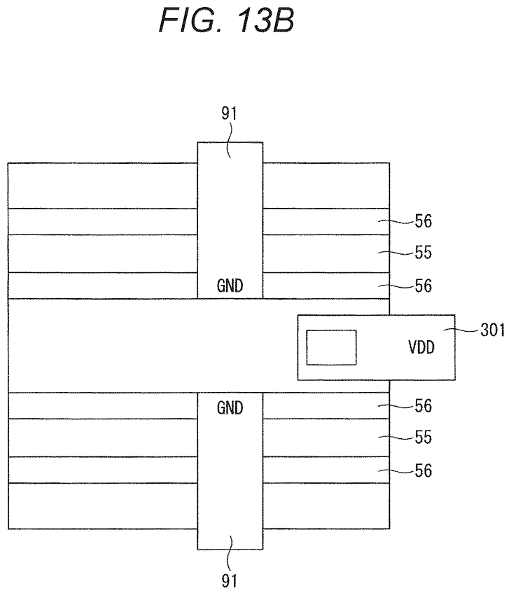

FIG. 13A is a plan view of a pixel region 13A and a peripheral region 13B of a photodetection device 1E according to the third embodiment of the present disclosure as viewed from a front surface 11a side of a first substrate 10. FIG. 13B is an enlarged view of a portion indicated by an alternate long and short dash line in peripheral region 13B in FIG. 13A. In FIGS. 13A and 13B, the same portions as those in the above-described FIG. 9 are denoted by the same reference signs, and detailed description thereof is omitted.

In the peripheral region 13B, the power supply section 301 is arranged between the two extended inter-pixel separation portions 55.

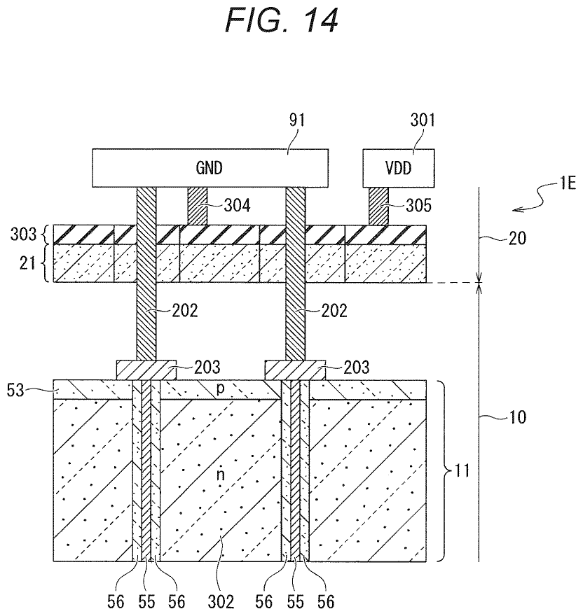

FIG. 14 is a partial longitudinal cross-sectional view illustrating an example of a semiconductor structure in a peripheral region 13B of a photodetection device 1E according to the third embodiment of the present disclosure. In FIG. 14, the same portions as those in the above-described FIG. 9 are denoted by the same reference signs, and detailed description thereof is omitted.

The inter-pixel separation portion 55 and the p-type layer 56 provided on the side wall of the inter-pixel separation portion 55 are extended to the n-type layer 302 of the peripheral region 13B. Furthermore, in the peripheral region 13B, the p-well 53 is laminated on the front surface side of the n-type layer 302, that is, the side on which the second substrate 20 is laminated. As a result, the peripheral region 13B has the same pixel structure as each sensor pixel 12.

The GND wiring 91 is electrically connected to the inter-pixel separation portion 55 and the p-type layer 56 via the through contact 202 and the shared poly 203. The through contact 202 penetrates the second substrate 20 and is connected to the shared poly 203 of the first substrate 10.

In the third embodiment of the present disclosure, in the second substrate 20, the wiring layer 303 is laminated on the back surface 21b of the second semiconductor substrate 21. The wiring layer 303 is a layer in which a metal wiring pattern for transmitting power and various drive signals to each sensor pixel 12 and applying a predetermined voltage to the readout circuit 22 is formed.

Furthermore, the GND wiring 91 is electrically connected to the second semiconductor substrate 21 provided on the second substrate 20 via the through contact 204. Consequently, the GND wiring 91 can be shared by the first substrate 10 and the second substrate 20.

Meanwhile, in the second embodiment of the present disclosure, the power supply section 301 is connected to the wiring layer 303 via the contact 305. As a result, a capacitance can be imparted between the through contacts 202 and 304 and the second semiconductor substrate 21 (silicon region) to which the power supply section 301 is connected.

### Functions and Effects of Third Embodiment

As described above, according to the third embodiment, by connecting from the shared poly 203 of the first substrate 10 to the wiring layer 303 through the through contacts 202 and 304 and sharing the GND wiring 91 between the first substrate 10 and the second substrate 20, it is possible to impart a capacitance between the through contacts 202 and 304 connecting the GND wiring 91 and the second semiconductor substrate 21 of the second substrate 20 to which the power supply section 301 is connected. As a result, it is possible to increase the total capacitance of the GND and suppress fluctuation in the coupling capacitance of the control line, the signal line, and the like in the sensor pixel 12.

Furthermore, according to the third embodiment, in the peripheral region 13B, the structure is the same as that of the sensor pixel 12, so that the position of the through contact 202 connecting the second substrate 20 to the GND wiring 91 can also be the same as that of the sensor pixel 12. This makes it possible to maintain the stability of the process without changing the structure.

### Modification of Third Embodiment

In a modification of the third embodiment of the present disclosure, each sensor pixel 12 is separated into two by the intra-pixel separation portions 311 and 312.

FIG. 15 is a plan view of a part of a pixel region 13A and a peripheral region 13B of a photodetection device 1F according to a modification of the third embodiment of the present disclosure as viewed from the front surface 11a side of the first substrate 10. In FIG. 15, the same portions as those in the above-described FIG. 9 are denoted by the same reference signs, and detailed description thereof is omitted.

The inter-pixel separation portion 55 includes a side 55a extending in the row direction (lateral direction in the drawing) and a side 55b extending in the column direction (longitudinal direction in the drawing). The sensor pixel 12 is surrounded by two sides 55a and two sides 55b. The intra-pixel separation portion 311 extends from one side 55a of the inter-pixel separation portion 55 to a substantially central portion of the sensor pixel 12. Furthermore, the intra-pixel separation portion 312 extends from the other side 55a of the inter-pixel separation portion 55 to a substantially central portion of the sensor pixel 12.

In the peripheral region 13B, the inter-pixel separation portion 55 and the intra-pixel separation portions 311 and 312 form the same structure as each sensor pixel 12. This makes it possible to maintain the stability of the process without changing the structure.

### Fourth Embodiment

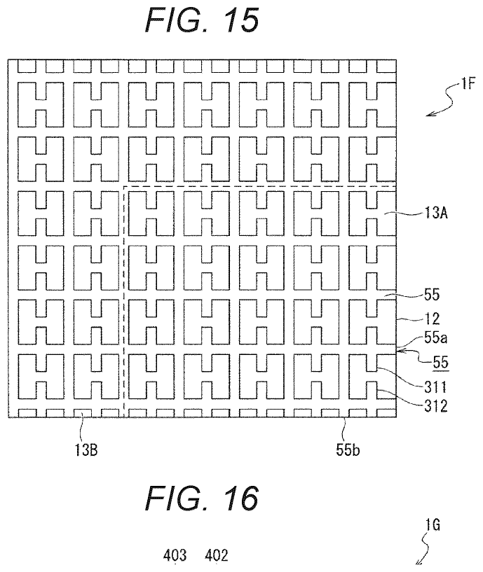

FIG. 16 is a plan view of a part of the pixel region 13A and the peripheral region 13B of the photodetection device 1G according to the fourth embodiment of the present disclosure as viewed from the front surface 11a side of the first substrate 10. In FIG. 16, the same portions as those in the above-described FIG. 9 are denoted by the same reference signs, and detailed description thereof is omitted.

The inter-pixel separation portion 55 and the p-type layer 56 provided on the side wall of the inter-pixel separation portion 55 are extended to the n-type layer 401 of the peripheral region 13B. A node 403 serving as a high-concentration n-type layer connected to the power supply section is provided between the high-concentration p-type layer 402 provided in each of the two inter-pixel separation portions 55.

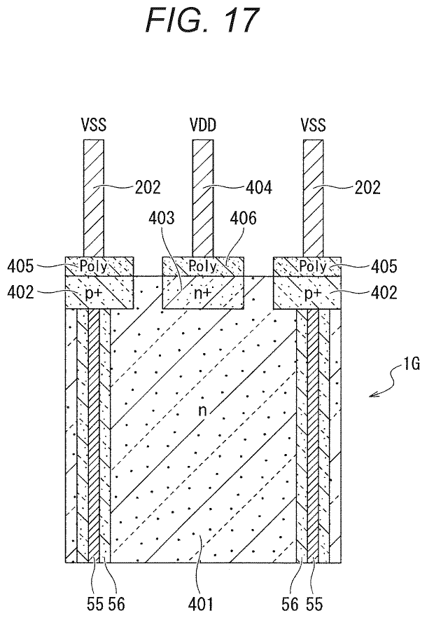

FIG. 17 schematically illustrates a cross section taken along line A-A′ of FIG. 16. The GND wiring 91 (VSS) is electrically connected to the inter-pixel separation portion 55 and the p-type layer 56 via the through contact 202, the shared poly 405, and the high-concentration p-type layer 402. The node 403 is connected to a power supply section (VDD) via a contact 404 and a shared poly 406.

### Functions and Effects of Fourth Embodiment

As described above, according to the fourth embodiment, in the peripheral region 13B, the high-concentration n-type node 403 connected to the power supply section is added between the inter-pixel separation portions 55 extending from the pixel region 13A, so that PN diffusion capacitance is obtained. Therefore, the VSS-VDD capacitance can be enhanced, and the robustness of the power supply can be improved.

### Modification of Fourth Embodiment

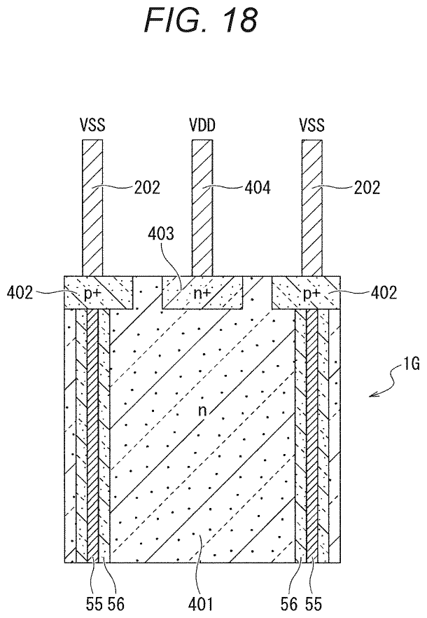

FIG. 18 is a partial longitudinal cross-sectional view illustrating an example of a semiconductor structure in a peripheral region 13B of a photodetection device 1H according to a modification of the fourth embodiment of the present disclosure. In FIG. 18, the same portions as those in the above-described FIG. 17 are denoted by the same reference signs, and detailed description thereof is omitted.

The modification of the fourth embodiment of the present disclosure is an example of a structure in which the shared poly 405,406 is not used in the pixel region 13A. Here, the contact 404 from the power supply section is directly connected to the node 403. In this manner, the manner of connecting the contacts 404 can also be changed in accordance with the structure of the pixel region 13A.

### Fifth Embodiment

In the fifth embodiment of the present disclosure, measures are taken in a case where there is no capacitance between VSS and VDD due to complete depletion.

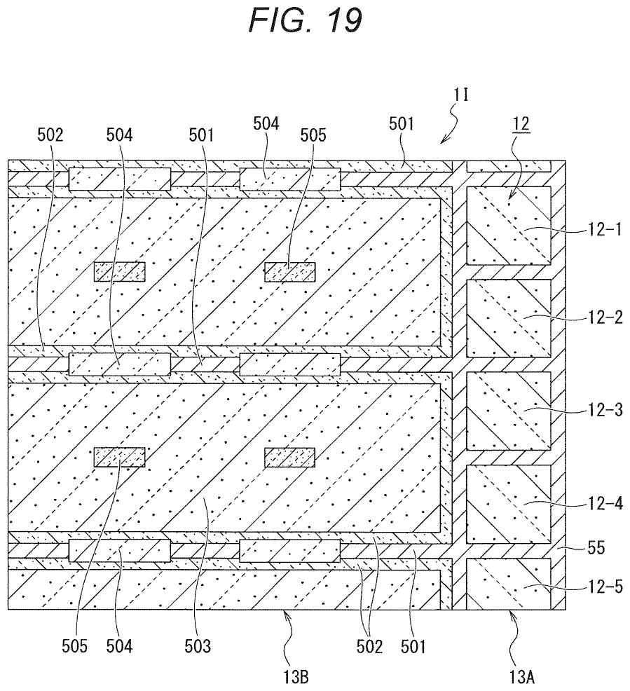

FIG. 19 is a plan view of a part of the pixel region 13A and the peripheral region 13B of the photodetection device 1I according to the fifth embodiment of the present disclosure as viewed from the front surface 11a side of the first substrate 10. In FIG. 19, the same portions as those in the above-described FIG. 16 are denoted by the same reference signs, and detailed description thereof is omitted.

Among the plurality of sensor pixels 12, sensor pixels 12-1 to 12-5 are arranged adjacent to each other in the column direction (vertical direction in the drawing). The inter-pixel separation portion 501 formed between the sensor pixel 12-2 and the sensor pixel 12-3 and the p-type layer 502 provided on the side wall of the inter-pixel separation portion 501 are extended to the n-type layer 401 of the peripheral region 13B. Furthermore, the inter-pixel separation portion 501 formed between the sensor pixel 12-4 and the sensor pixel 12-5 and the p-type layer 502 provided on the side wall of the inter-pixel separation portion 501 are extended to the n-type layer 401 of the peripheral region 13B. That is, the inter-pixel separation portion 501 and the p-type layer 502 are extended to the peripheral region 13B at an interval of one sensor pixel 12.

A node 505 serving as a high-concentration n-type layer connected to the power supply section is provided between the high-concentration p-type layer 504 provided in each of the two inter-pixel separation portions 501.

### Functions and Effects of Fifth Embodiment

As described above, according to the fifth embodiment, in a case where there is no capacitance due to complete depletion, it is possible to avoid the case by increasing the interval between the inter-pixel separation portion 501 and the p-type layer 502 in the peripheral region 13B to separate the n-type region and the p-type region. Note that in the fifth embodiment, one inter-pixel separation portion 501 and one p-type layer 502 are skipped for stretching, but two may be skipped depending on the degree of capacitance at that time.

### Sixth Embodiment

In the sixth embodiment of the present disclosure, similarly to the fifth embodiment, measures are taken in a case where there is no capacitance between VSS and VDD due to complete depletion.

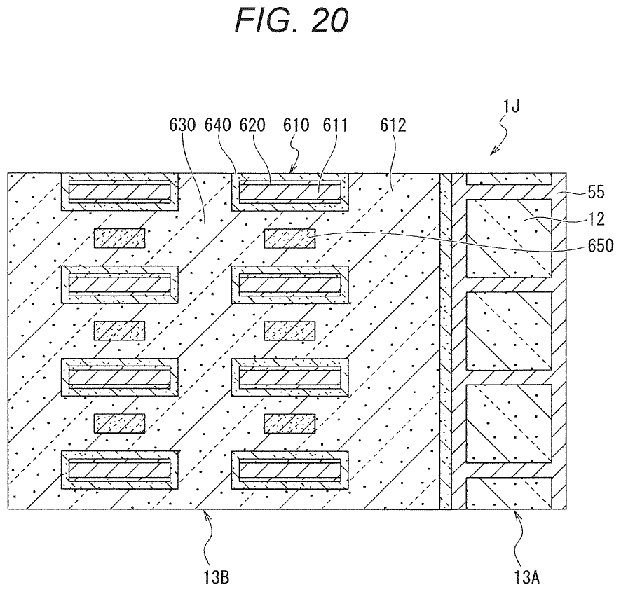

FIG. 20 is a plan view of a part of the pixel region 13A and the peripheral region 13B of the photodetection device 1J according to the sixth embodiment of the present disclosure as viewed from the front surface 11a side of the first substrate 10. In FIG. 20, the same portions as those in the above-described FIG. 16 are denoted by the same reference signs, and detailed description thereof is omitted.

The inter-pixel separation portion 610 extending from the pixel region 13A and the p-type layer 620 provided on the side wall of the inter-pixel separation portion 610 extend to the n-type layer 630 of the peripheral region 13B. The inter-pixel separation portion 610 is a dotted line type in which the separation region 611 in which the conductive material having the full trench structure is formed and the separation region 612 in which the conductive material is not formed are alternately arranged. In addition, the p-type layer 620 and the high-concentration p-type layer 640 are provided only in the separation region 611.

A node 650 serving as a high-concentration n-type layer connected to the power supply section is provided between the high-concentration p-type layer 640 provided in each of the two inter-pixel separation portions 610.

### Functions and Effects of Sixth Embodiment

As described above, according to the sixth embodiment, by extending the inter-pixel separation portion 610 in the dotted line type in the peripheral region 13B, the implantation amount of p-type impurities is reduced, and complete depletion is avoided. Note that a combination with the fifth embodiment described above is also possible depending on the degree of capacitance.

### Seventh Embodiment

The seventh embodiment of the present disclosure is a modification of the sixth embodiment.

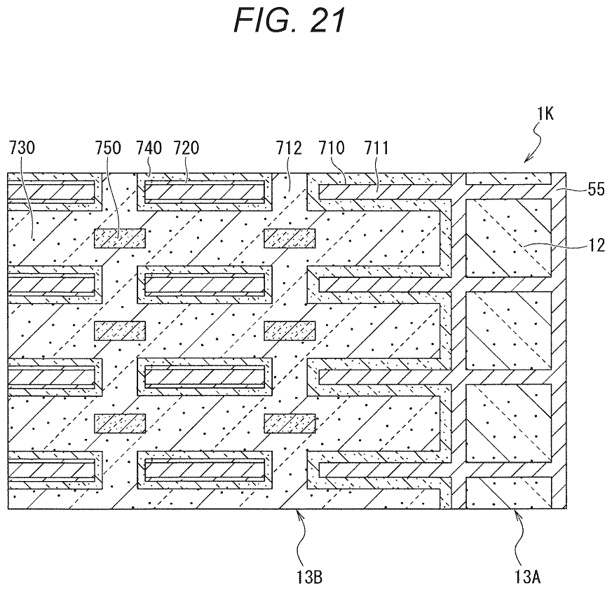

FIG. 21 is a plan view of a part of the pixel region 13A and the peripheral region 13B of the photodetection device 1K according to the seventh embodiment of the present disclosure as viewed from the front surface 11a side of the first substrate 10. In FIG. 21, the same portions as those in the above-described FIG. 16 are denoted by the same reference signs, and detailed description thereof is omitted.

The inter-pixel separation portion 710 extending from the pixel region 13A and the p-type layer 720 provided on the side wall of the inter-pixel separation portion 710 extend to the n-type layer 730 of the peripheral region 13B. The inter-pixel separation portion 710 is a dotted line type in which the separation region 711 in which the conductive material having the full trench structure is formed and the separation region 712 in which the conductive material is not formed are alternately arranged. In addition, the p-type layer 720 and the high-concentration p-type layer 740 are provided only in the separation region 711.

A node 750 serving as a high-concentration n-type layer connected to the power supply section is provided between the separation region 712 in each of the two inter-pixel separation portions 710.

### Functions and Effects of Seventh Embodiment

As described above, according to the seventh embodiment, by adopting a structure in which the high-concentration n-type node 750 and the high-concentration p-type layer 740 are not arranged in the peripheral region 13B, the potential under the high-concentration n-type node 750 is deepened, and capacitance is easily added.

### Eighth Embodiment

The eighth embodiment of the present disclosure is a modification of the sixth embodiment and the seventh embodiment.

FIG. 22 is a plan view of a part of the pixel region 13A and the peripheral region 13B of the photodetection device 1L according to the eighth embodiment of the present disclosure as viewed from the front surface 11a side of the first substrate 10. In FIG. 22, the same portions as those in the above-described FIG. 16 are denoted by the same reference signs, and detailed description thereof is omitted.

In the peripheral region 13B, the inter-pixel separation portion 810 and the p-type layer 820 provided on the side wall of the inter-pixel separation portion 810 are arranged in the n-type layer 830 of the peripheral region 13B. The inter-pixel separation portion 810 is a dotted line type in which the separation region 811 in which the conductive material having the full trench structure is formed and the separation region 812 in which the conductive material is not formed are alternately arranged. In addition, the p-type layer 820 and the high-concentration p-type layer 840 are provided only in the separation region 811.

A node 850 serving as a high-concentration n-type layer connected to the power supply section is provided between the separation region 812 in each of the two inter-pixel separation portions 810. Meanwhile, in the eighth embodiment, the inter-pixel separation portion 810 does not extend from the pixel region 13A, and extends in a direction (vertical direction in the drawing) orthogonal to the extending direction of the inter-pixel separation portion 55 in the pixel region 13A.

### Functions and Effects of Eighth Embodiment

As described above, according to the eighth embodiment, functions and effects similar to those of the sixth embodiment and the seventh embodiment can be obtained.

### Other Embodiments

As described above, the present technology has been described by the first to eighth embodiments, the modifications of the first embodiment, the first to third modifications of the second embodiment, the modifications of the third embodiment, and the modifications of the fourth embodiment, but it should not be understood that the description and the drawings constituting a part of this disclosure limit the present technology. It will be apparent to those skilled in the art that various alternative embodiments, examples, and operation techniques can be included in the present technology when understanding the spirit of the technical content disclosed in the first to eighth embodiments described above. In addition, the configurations disclosed in the first to eighth embodiments, the modifications of the first embodiment, the first to third modifications of the second embodiment, the modifications of the third embodiment, and the modifications of the fourth embodiment can be appropriately combined within a range in which no contradiction occurs. For example, configurations disclosed in a plurality of different embodiments may be combined, or configurations disclosed in a plurality of different modifications of the same embodiment may be combined.

### <Application Example to Electronic Apparatus>

The photodetection device described above can be applied to various electronic apparatuses such as, for example, an imaging device such as a digital still camera and a digital video camera, a mobile phone with an imaging function, or other devices having an imaging function.

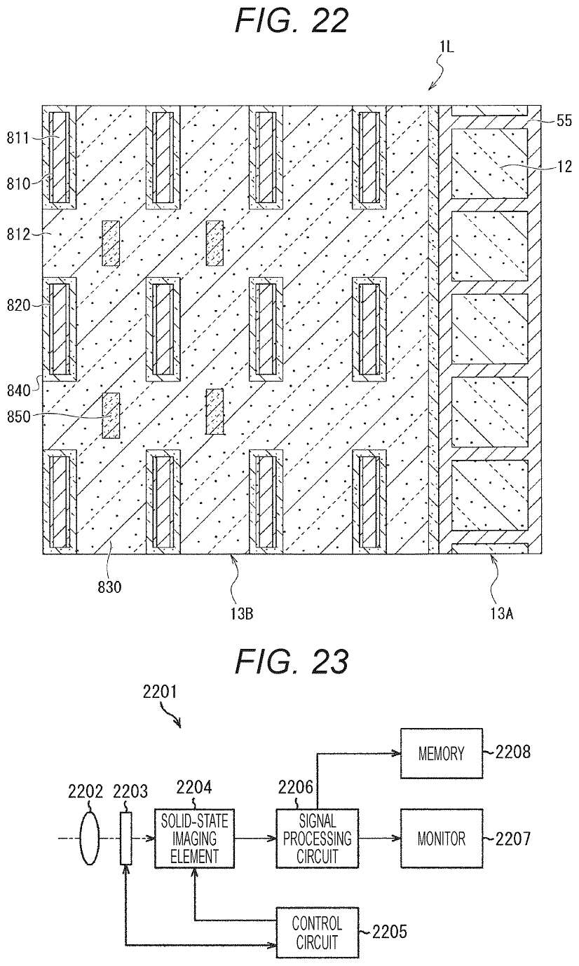

FIG. 23 is a block diagram illustrating a configuration example of an imaging device as an electronic apparatus to which the present technology is applied.

An imaging device 2201 illustrated in FIG. 23 includes an optical system 2202, a shutter device 2203, a solid-state imaging element 2204 as a photodetection device, a control circuit 2205, a signal processing circuit 2206, a monitor 2207, and two memories 2208, and can capture a still image and a moving image.

The optical system 2202 includes one or a plurality of lenses, and guides light from a subject (incident light) to the solid-state imaging element 2204 to form an image on a light receiving surface of the solid-state imaging element 2204.

The shutter device 2203 arranged between the optical system 2202 and the solid-state imaging element 2204 controls a light irradiation period to the solid-state imaging element 2204 and a light shielding period according to control of the control circuit 2205.

The solid-state imaging element 2204 includes a package including the solid-state imaging element described above. The solid-state imaging element 2204 accumulates a signal charge for a certain period according to the light the image of which is formed as an image on the light receiving surface via the optical system 2202 and the shutter device 2203. The signal charges accumulated in the solid-state imaging element 2204 are transferred according to a drive signal (timing signal) supplied from the control circuit 2205.

The control circuit 2205 outputs the drive signal to control a transfer operation of the solid-state imaging element 2204 and a shutter operation of the shutter device 2203 to drive the solid-state imaging element 2204 and the shutter device 2203.

The signal processing circuit 2206 performs various types of signal processing on the signal charges output from the solid-state imaging element 2204. An image (image data) obtained by the signal processing circuit 2206 performing the signal processing is supplied to the monitor 2207 to be displayed or supplied to the memory 2208 to be stored (recorded).

Also in the imaging device 2201 configured as described above, the photodetection devices 1, 1A, 1B, 1C, 1D, 1E, 1F, 1G, 1H, 1I, 1J, 1K, and 1L can be applied instead of the solid-state imaging element 2204 described above.

### <Application Example to Endoscopic Surgery System>

The technology according to the present disclosure (the present technology) can be applied to various products. For example, the technology according to the present disclosure may be applied to an endoscopic surgery system.

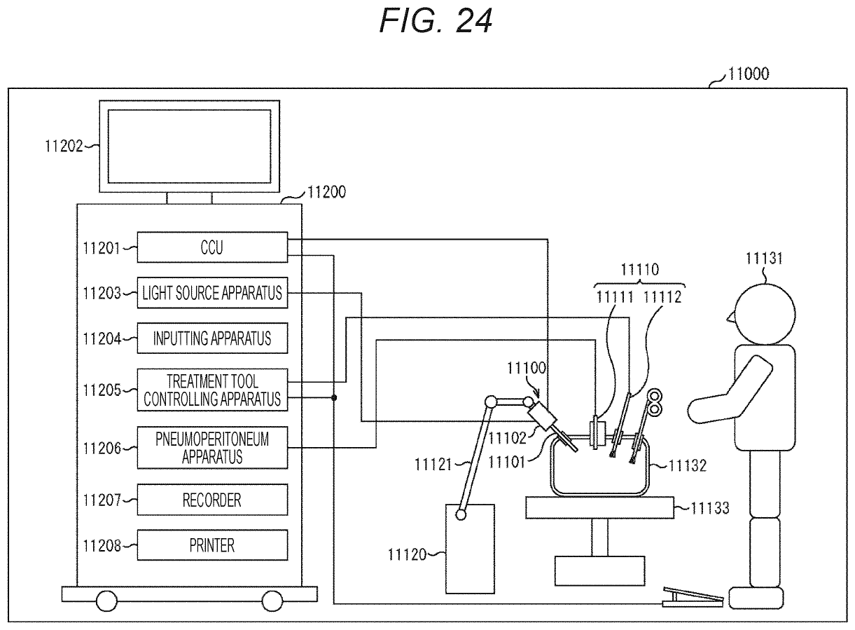

FIG. 24 is a view depicting an example of a schematic configuration of an endoscopic surgery system to which the technology according to an embodiment of the present disclosure (present technology) can be applied.

In FIG. 24, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as a light emitting diode (LED), for example, and supplies irradiation light for imaging a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

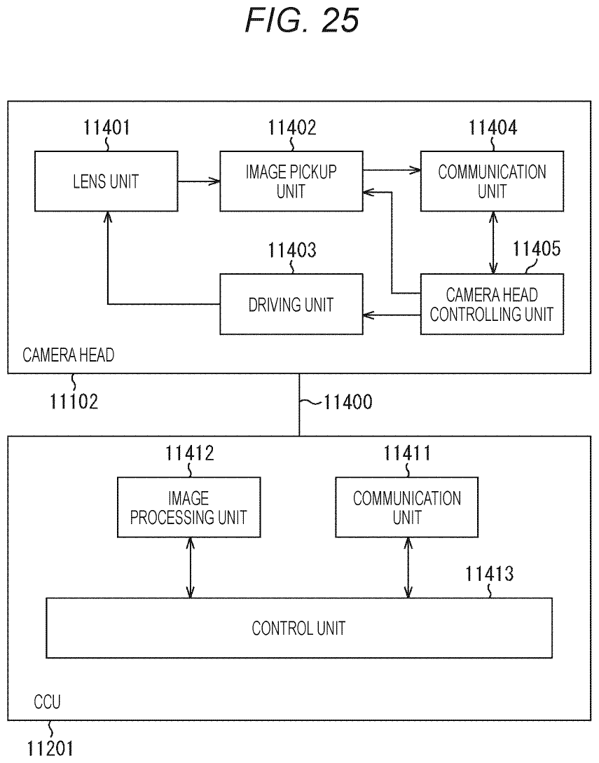

FIG. 25 is a block diagram depicting an example of a functional configuration of the camera head 11102 and the CCU 11201 depicted in FIG. 24.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to, for example, the endoscope 11100, the image pickup unit 11402 of the camera head 11102, the image processing unit 11412 of the CCU 11201, and the like among the above-described configurations. Specifically, the photodetection device 1 of FIG. 1 can be applied to the image pickup unit 10402.

Note that an endoscopic surgery system has been described as an example herein, but the technology according to the present disclosure may be applied to a microscopic surgery system or the like, for example.

### <Application Example to Mobile Body>

The technology according to the present disclosure (the present technology) can be applied to various products. For example, the technology according to the present disclosure may be implemented as a device mounted on any type of mobile bodies such as an automobile, an electric vehicle, a hybrid electric vehicle, a motorcycle, a bicycle, a personal mobility, an airplane, a drone, a ship, a robot, and the like.

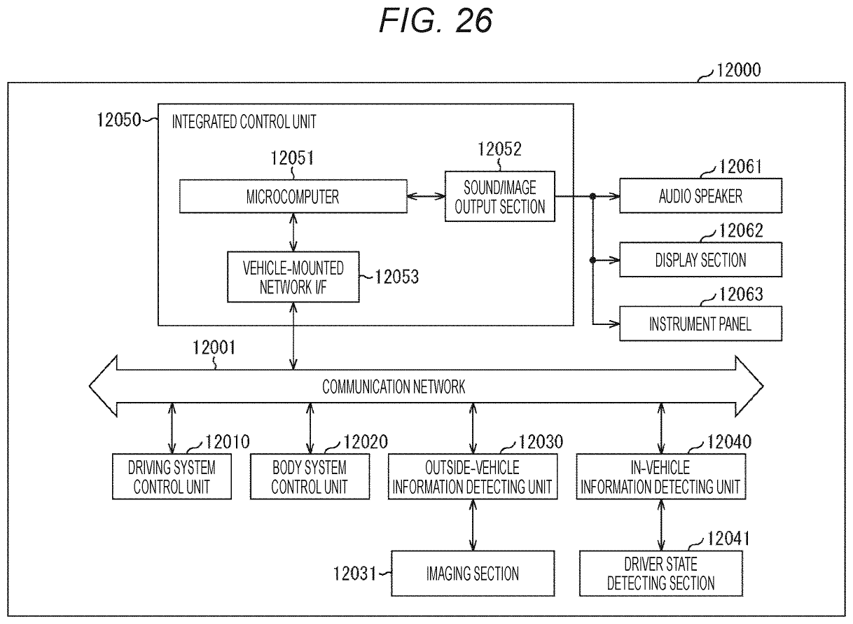

FIG. 26 is a block diagram depicting a schematic configuration example of a vehicle control system as an example of a mobile body control system to which the technology according to the present disclosure can be applied.

The vehicle control system 12000 includes a plurality of electronic control units connected to each other via a communication network 12001. In the example depicted in FIG. 26, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 26, an audio speaker 12061, a display section 12062, and an instrument panel 12063 are illustrated as the output device. The display section 12062 may, for example, include at least one of an on-board display and a head-up display.

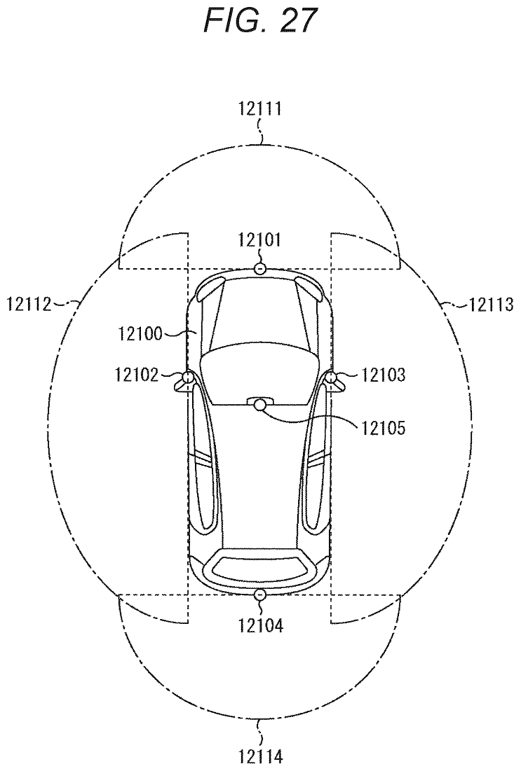

FIG. 27 is a diagram depicting an example of an installation position of the imaging section 12031.

In FIG. 27, the vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle or the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 23 illustrates an example of capturing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of a vehicle control system to which the technology according to the present disclosure can be applied has been described above. The technology according to the present disclosure can be applied to the imaging section 12031 and the like, for example, among the configurations described above. Specifically, the technology can be applied to the photodetection device 1 in FIG. 1.

Note that the present disclosure can also have the following configurations.

(1)

A photodetection device including a substrate portion including a pixel region in which a plurality of pixels capable of generating charges according to light incident from outside is arranged in a matrix, and a peripheral region different from the pixel region,
in which each of the plurality of pixels includes
a plurality of inter-pixel separation portions that defines an outer edge of the pixel, is formed to extend from a light incident surface of the substrate portion to a surface opposite to the light incident surface, and insulates and shields the pixels adjacent,
at least a part of the plurality of inter-pixel separation portions is formed to extend to the peripheral region, and
a grounding portion connectable to the inter-pixel separation portion and configured to apply a predetermined voltage to the pixel via the inter-pixel separation portion is provided in the peripheral region.
   (2)

The photodetection device according to (1), in which the plurality of inter-pixel separation portions is formed to extend to the peripheral region for each pixel,
the pixel is a region of a first conductivity type, and a region of a second conductivity type opposite to the region of the first conductivity type is provided on a side wall of the inter-pixel separation portion, and
the peripheral region includes a node of the first conductivity type provided between the plurality of inter-pixel separation portions and connected to a power supply section.
   (3)

The photodetection device according to (2), in which the grounding portion is connected to the inter-pixel separation portion via a shared poly, and
the node of the first conductivity type is connected to the power supply section via the shared poly.
   (4)

The photodetection device according to (2), in which the plurality of inter-pixel separation portions is formed by extending a first inter-pixel separation portion formed between a first pixel and a second pixel and a second inter-pixel separation portion formed between an adjacent third pixel and a fourth pixel among the first to fourth pixels adjacent of the plurality of pixels to the peripheral region, and
the node of the first conductivity type is arranged between the first inter-pixel separation portion and the second inter-pixel separation portion.
   (5)

The photodetection device according to (2), in which the plurality of inter-pixel separation portions extending to the peripheral region is a dotted line type formed by alternately arranging a first separation region in which a conductive material is formed and a second separation region in which the conductive material is not formed, and
the node of the first conductivity type is provided between the first separation regions of the plurality of inter-pixel separation portions.
   (6)

The photodetection device according to (2), in which the plurality of inter-pixel separation portions extending to the peripheral region is a dotted line type formed by alternately arranging a first separation region in which a conductive material is formed and a second separation region in which the conductive material is not formed, and
the node of the first conductivity type is provided between the second separation regions of the plurality of inter-pixel separation portions.
   (7)

A photodetection device including: a first substrate portion including a pixel region in which a plurality of pixels capable of generating charges according to light incident from outside is arranged in a matrix, and a peripheral region different from the pixel region; and
a second substrate portion laminated on an element surface of the first substrate portion on a side opposite to a light incident surface on which the light is incident, the second substrate portion including a readout circuit that outputs a pixel signal based on a charge output from the pixel,
in which each of the plurality of pixels includes
a plurality of inter-pixel separation portions that defines an outer edge of the pixel, is formed to extend from the light incident surface of the first substrate portion to the element surface, and insulates and shields the pixels adjacent,
the inter-pixel separation portion is formed to extend to the peripheral region, and
a grounding portion connectable to the inter-pixel separation portion and configured to apply a predetermined voltage to the pixel via the inter-pixel separation portion is provided in the peripheral region.
   (8)

The photodetection device according to (7), further including a plurality of through contacts that connects the first substrate portion and the second substrate portion,
in which one end side of at least some of the plurality of through contacts is connected to the inter-pixel separation portion via a shared poly in the peripheral region, and an other end side penetrates the second substrate portion and is connected to the grounding portion.
   (9)

The photodetection device according to (8), in which the second substrate portion includes a wiring layer having a metal wiring pattern for applying a predetermined voltage to the readout circuit on an opposite side on which the first substrate portion is laminated, and
the grounding portion is connected to the wiring layer via the through contact.
   (10)

The photodetection device according to (7), in which the peripheral region forms a same structure as a structure of each of a plurality of pixels arranged in the pixel region by the inter-pixel separation portion extending from the pixel region.

(11)

The photodetection device according to (10), in which in the pixel region, the pixel is a first conductivity type region, and a second conductivity type region opposite to the first conductivity type region is provided on a side wall of the inter-pixel separation portion, and
the peripheral region is provided with the second conductivity type region on a side wall of the inter-pixel separation portion extended.
   (12)

The photodetection device according to (10), in which each of the plurality of pixels includes an intra-pixel separation portion that extends from a side portion of the inter-pixel separation portion to a central portion of the pixel and separates the pixel into two, and
the peripheral region forms a same structure as a structure of each of a plurality of pixels arranged in the pixel region by the inter-pixel separation portion and the intra-pixel separation portion.
   (13)

The photodetection device according to (8), in which the first substrate portion includes, in the peripheral region, a first poly wiring connected to a through contact penetrating the second substrate portion from the grounding portion, and a plurality of second poly wirings formed to surround the first poly wiring.

(14)

The photodetection device according to (8), in which the first substrate portion includes a plurality of poly wirings formed to surround a through contact connected to the shared poly in the peripheral region.

(15)

The photodetection device according to (8), in which the first substrate portion includes, in the peripheral region, a first poly wiring penetrating and connected to a through contact connected to the shared poly, and a plurality of second poly wirings formed to surround the first poly wiring.

(16)

The photodetection device according to (8), in which the grounding portion is connected to a gate oxide film of a field effect transistor provided on the second substrate portion.

(17)

An electronic apparatus including a photodetection device including a substrate portion including a pixel region in which a plurality of pixels capable of generating charges according to light incident from outside is arranged in a matrix, and a peripheral region different from the pixel region,
in which each of the plurality of pixels includes
a plurality of inter-pixel separation portions that defines an outer edge of the pixel, is formed to extend from a light incident surface of the substrate portion to a surface opposite to the light incident surface, and insulates and shields the pixels adjacent,
at least a part of the plurality of inter-pixel separation portions is formed to extend to the peripheral region, and
a grounding portion connectable to the inter-pixel separation portion and configured to apply a predetermined voltage to the pixel via the inter-pixel separation portion is provided in the peripheral region.
   (18)

An electronic apparatus including a photodetection device including: a first substrate portion including a pixel region in which a plurality of pixels capable of generating charges according to light incident from outside is arranged in a matrix, and a peripheral region different from the pixel region; and
a second substrate portion laminated on an element surface of the first substrate portion on a side opposite to a light incident surface on which the light is incident, the second substrate portion including a readout circuit that outputs a pixel signal based on a charge output from the pixel,
in which each of the plurality of pixels includes
a plurality of inter-pixel separation portions that defines an outer edge of the pixel, is formed to extend from the light incident surface of the first substrate portion to the element surface, and insulates and shields the pixels adjacent,
the inter-pixel separation portion is formed to extend to the peripheral region, and
a grounding portion connectable to the inter-pixel separation portion and configured to apply a predetermined voltage to the pixel via the inter-pixel separation portion is provided in the peripheral region.

### REFERENCE SIGNS LIST

1, 1A, 1B, 1C, 1D, 1E, 1F, 1G, 1H, 1I, 1J, 1K, 1L Photodetection device
10 First substrate
11 First semiconductor substrate
11a, 21a Front surface
11b, 21b Back surface
12, 12-1, 12-2, 12-3, 12-4, 12-5 Sensor pixel
13A Pixel region
13B Peripheral region
14 Bonding pad
15 Second substrate
21 Second semiconductor substrate
22 Readout circuit
23 Pixel drive line
24 Vertical signal line
25 Third substrate
31 Third semiconductor substrate
32 Logic circuit
33 Vertical drive circuit
34 Column signal processing circuit
35 Horizontal drive circuit
36 System control circuit
51 High-concentration n-type layer (n-type diffusion layer)
52 High-concentration p-type layer (p-type diffusion layer)
53, 71 p-well
53a, 56 p-type layer
54, 57 n-type layer
55 Inter-pixel separation portion
55a, 55b Side
72 Element isolation layer
73 High-concentration p-type layer
74 High-concentration n-type layer
75 Source portion
76 Drain portion
77 Source portion
78, 79 High-concentration n-type layer
81 Insulating film
82 Interlayer insulating film
91 GND wiring
92, 93, 305, 404 Contact
94 Poly
101, 201, 630, 730 n-type layer
102, 402, 504, 640, 740, 840 High-concentration p-type layer
202, 204, 207, 212, 222, 232, 304 Through contact
203, 405, 406 Shared poly
205 First poly wiring
206 Second poly wiring
211, 221, 302, 401, 830 n-type layer
223 Poly wiring
231 Gate oxide film
301 Power supply section
303 Wiring layer
311, 312 Intra-pixel separation portion
403, 505, 650, 750, 850 Node
501, 610 Inter-pixel separation portion
502, 602, 720, 820 p-type layer
610, 710, 810 Inter-pixel separation portion
611, 612, 711, 712, 811, 812 Separation region
2201 Imaging device
2202 Optical system
2203 Shutter device
2204 Solid-state imaging element
2205 Control circuit
2206 Signal processing circuit
2207 Monitor
2208 Memory
10402 Image pickup unit
11000 Endoscopic surgery system
11100 Endoscope
11101 Lens barrel
11102 Camera head
11110 Surgical tool
11111 Pneumoperitoneum tube
11112 Energy device
11120 Supporting arm apparatus
11131 Surgeon (medical doctor)
11132 Patient
11133 Patient bed
11200 Cart
11201 Camera control unit (CCU)
11202 Display apparatus
11203 Light source apparatus
11204 Inputting apparatus
11205 Treatment tool controlling apparatus
11206 Pneumoperitoneum apparatus
11207 Recorder
11208 Printer
11400 Transmission cable
11401 Lens unit
11402 Image pickup unit
11403 Driving section
11404 Communication section
11405 Camera head controlling section
11411 Communication section
11412 Image processing section
11413 Control section
12000 Vehicle control system
12001 Communication network
12010 Driving system control unit
12020 Body system control unit
12030 Outside-vehicle information detecting unit
12031 Imaging section
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101 to 12105 Imaging section
12111 to 12114 Imaging range

1. A photodetection device comprising a substrate portion including a pixel region in which a plurality of pixels capable of generating charges according to light incident from outside is arranged in a matrix, and a peripheral region different from the pixel region,
wherein each of the plurality of pixels includes
a plurality of inter-pixel separation portions that defines an outer edge of the pixel, is formed to extend from a light incident surface of the substrate portion to a surface opposite to the light incident surface, and insulates and shields the pixels adjacent,
at least a part of the plurality of inter-pixel separation portions is formed to extend to the peripheral region, and
a grounding portion connectable to the inter-pixel separation portion and configured to apply a predetermined voltage to the pixel via the inter-pixel separation portion is provided in the peripheral region.

2. The photodetection device according to claim 1, wherein the plurality of inter-pixel separation portions is formed to extend to the peripheral region for each pixel,
the pixel is a region of a first conductivity type, and a region of a second conductivity type opposite to the region of the first conductivity type is provided on a side wall of the inter-pixel separation portion, and
the peripheral region includes a node of the first conductivity type provided between the plurality of inter-pixel separation portions and connected to a power supply section.

3. The photodetection device according to claim 2, wherein the grounding portion is connected to the inter-pixel separation portion via a shared poly, and
the node of the first conductivity type is connected to the power supply section via the shared poly.

4. The photodetection device according to claim 2, wherein the plurality of inter-pixel separation portions is formed by extending a first inter-pixel separation portion formed between a first pixel and a second pixel and a second inter-pixel separation portion formed between an adjacent third pixel and a fourth pixel among the first to fourth pixels adjacent of the plurality of pixels to the peripheral region, and
the node of the first conductivity type is arranged between the first inter-pixel separation portion and the second inter-pixel separation portion.

5. The photodetection device according to claim 2, wherein the plurality of inter-pixel separation portions extending to the peripheral region is a dotted line type formed by alternately arranging a first separation region in which a conductive material is formed and a second separation region in which the conductive material is not formed, and
the node of the first conductivity type is provided between the first separation regions of the plurality of inter-pixel separation portions.

6. The photodetection device according to claim 2, wherein the plurality of inter-pixel separation portions extending to the peripheral region is a dotted line type formed by alternately arranging a first separation region in which a conductive material is formed and a second separation region in which the conductive material is not formed, and
the node of the first conductivity type is provided between the second separation regions of the plurality of inter-pixel separation portions.

7. A photodetection device comprising: a first substrate portion including a pixel region in which a plurality of pixels capable of generating charges according to light incident from outside is arranged in a matrix, and a peripheral region different from the pixel region; and
a second substrate portion laminated on an element surface of the first substrate portion on a side opposite to a light incident surface on which the light is incident, the second substrate portion including a readout circuit that outputs a pixel signal based on a charge output from the pixel,
wherein each of the plurality of pixels includes
a plurality of inter-pixel separation portions that defines an outer edge of the pixel, is formed to extend from the light incident surface of the first substrate portion to the element surface, and insulates and shields the pixels adjacent,
the inter-pixel separation portion is formed to extend to the peripheral region, and
a grounding portion connectable to the inter-pixel separation portion and configured to apply a predetermined voltage to the pixel via the inter-pixel separation portion is provided in the peripheral region.

8. The photodetection device according to claim 7, further comprising a plurality of through contacts that connects the first substrate portion and the second substrate portion,
wherein one end side of at least some of the plurality of through contacts is connected to the inter-pixel separation portion via a shared poly in the peripheral region, and an other end side penetrates the second substrate portion and is connected to the grounding portion.

9. The photodetection device according to claim 8, wherein the second substrate portion includes a wiring layer having a metal wiring pattern for applying a predetermined voltage to the readout circuit on an opposite side on which the first substrate portion is laminated, and
the grounding portion is connected to the wiring layer via the through contact.

10. The photodetection device according to claim 7, wherein the peripheral region forms a same structure as a structure of each of a plurality of pixels arranged in the pixel region by the inter-pixel separation portion extending from the pixel region.

11. The photodetection device according to claim 10, wherein in the pixel region, the pixel is a first conductivity type region, and a second conductivity type region opposite to the first conductivity type region is provided on a side wall of the inter-pixel separation portion, and
the peripheral region is provided with the second conductivity type region on a side wall of the inter-pixel separation portion extended.

12. The photodetection device according to claim 10, wherein each of the plurality of pixels includes an intra-pixel separation portion that extends from a side portion of the inter-pixel separation portion to a central portion of the pixel and separates the pixel into two, and
the peripheral region forms a same structure as a structure of each of a plurality of pixels arranged in the pixel region by the inter-pixel separation portion and the intra-pixel separation portion.

13. The photodetection device according to claim 8, wherein the first substrate portion includes, in the peripheral region, a first poly wiring connected to a through contact penetrating the second substrate portion from the grounding portion, and a plurality of second poly wirings formed to surround the first poly wiring.

14. The photodetection device according to claim 8, wherein the first substrate portion includes a plurality of poly wirings formed to surround a through contact connected to the shared poly in the peripheral region.

15. The photodetection device according to claim 8, wherein the first substrate portion includes, in the peripheral region, a first poly wiring penetrating and connected to a through contact connected to the shared poly, and a plurality of second poly wirings formed to surround the first poly wiring.

16. The photodetection device according to claim 8, wherein the grounding portion is connected to a gate oxide film of a field effect transistor provided on the second substrate portion.

17. An electronic apparatus comprising a photodetection device comprising a substrate portion including a pixel region in which a plurality of pixels capable of generating charges according to light incident from outside is arranged in a matrix, and a peripheral region different from the pixel region,
wherein each of the plurality of pixels includes
a plurality of inter-pixel separation portions that defines an outer edge of the pixel, is formed to extend from a light incident surface of the substrate portion to a surface opposite to the light incident surface, and insulates and shields the pixels adjacent,
at least a part of the plurality of inter-pixel separation portions is formed to extend to the peripheral region, and
a grounding portion connectable to the inter-pixel separation portion and configured to apply a predetermined voltage to the pixel via the inter-pixel separation portion is provided in the peripheral region.

18. An electronic apparatus comprising a photodetection device comprising: a first substrate portion including a pixel region in which a plurality of pixels capable of generating charges according to light incident from outside is arranged in a matrix, and a peripheral region different from the pixel region; and
a second substrate portion laminated on an element surface of the first substrate portion on a side opposite to a light incident surface on which the light is incident, the second substrate portion including a readout circuit that outputs a pixel signal based on a charge output from the pixel,
wherein each of the plurality of pixels includes
a plurality of inter-pixel separation portions that defines an outer edge of the pixel, is formed to extend from the light incident surface of the first substrate portion to the element surface, and insulates and shields the pixels adjacent,
the inter-pixel separation portion is formed to extend to the peripheral region, and
a grounding portion connectable to the inter-pixel separation portion and configured to apply a predetermined voltage to the pixel via the inter-pixel separation portion is provided in the peripheral region.
